(19) United States
(12) Patent Application Publication
(10) Pub. No.: US 2017/0328544 A1
(43) Pub. Date: Nov. 16, 2017

(54) SNAP-IN ASSEMBLING OF LED BOARDS IN LUMINAIRES

(71) Applicant: GE Lighting Solutions, LLC, East Cleveland, OH (US)

(72) Inventors: Jacint GERGELY, Budapest (HU); Istvan Gyork SZILAGYI, Budapest (HU); Zoltan SEJPES, Budapest (HU)

(21) Appl. No.: 15/155,187

(22) Filed: May 16, 2016

(51) Int. Cl. F21V 19/00; F21S 4/28; H05K 1/18

(52) U.S. Cl. CPC F21V 19/004; H05K 1/181; F21S 4/28; H05K 2201/10106

(57) ABSTRACT

The specification and drawings present a new lighting/housing fixture comprising a plate/housing plate having multiple snapping clips for holding/assembling LED boards/modules in luminaires/LED light fixtures. The assembly can be made without any fasteners (such as rivets, screws, embossed fasteners, etc.), adhesives or any additional materials. This may be achieved by forming a housing plate comprising a plurality of snapping clips, made from one plate using, e.g., a sheet metal. The snapping clips are able to hold the LED boards in place, using snapped claws, as tight as conventional methods (e.g., using fasteners, rivets, etc.). In addition, the described housing fixture can simplify the assembling procedure, and reduce cost, manpower and maintenance compared to the conventional methods.

### TECHNICAL FIELD

The invention generally relates to lighting systems. More particularly but not exclusively, this invention relates to snap-in assembling of LED boards/modules in luminaires/LED housing fixtures.

### BACKGROUND OF THE INVENTION

LED (light emitting diode) printed circuit boards (PCBs) are conventionally assembled on a housing fixture/housing plate using fasteners. For example, a conventional approach, using fasteners like pop-rivets, may be used. This requires using riveting machine, alignment procedure, and additional fasteners/rivets. To hold PCBs properly aligned, the process may require at least 3 rivets for each LED board, and at least two people for proper positioning/alignment. In addition, this approach may be further inefficient because of the required machine maintenance, and preparation on the housing plate by pre-cutting corresponding sports for placing the rivets. Also, riveting process could fail if the painting on the housing is too thick since the riveting pistol is usually set to a certain air pressure. Then, if the pop-rivets can be stuck, the holding force could be insufficient, and the PCBs could fall off the housing. In this case the LED lamp (comprising LED boards) should be changed at a site of installation. More reliable and less costly approach is desired.

### SUMMARY OF THE INVENTION

According to an aspect of the invention, a housing fixture for assembling light emitting diode (LED) boards, the housing fixture comprising: a plate (made of a sheet of metal, aluminum, steel, etc.), configured to hold one or more LED boards (which could be removable), the plate comprising: one or more rows of snapping clips (identical or non-identical) protruding from one surface of the plate and made by cutting and bending predefined features on the plate, each row comprises a plurality of snapping clips (e.g., two, three, etc.) for snapping a corresponding LED board of the one or more LED boards, wherein each snapping clip of the plurality of snapping clips is configured, when one of the one or more LED boards in a corresponding row of the one or more rows is moved to a predefined position between the plate and each snapping clip, to snap against a corresponding opening in a housing wall of the one LED board using a snapping feature (e.g., a claw having a round shape, rectangular shape or the like) of each snapping clip, to lock the one LED board with the plate without any further components, fasteners or adhesives.

According further to the aspect of the invention, the corresponding snapping feature can move upward from the plate when the corresponding one LED board is moved toward the predefined position between the plate and the corresponding snapping clip, and, when the predefined position is reached, the snapping feature can move downward to the corresponding opening in the housing wall of the one LED board to snap.

Still further according to the aspect of the invention, the each snapping clip may comprise: a first portion connected to and bent to extend from the one surface of the plate through a first bending joint, the first portion is arranged to extend along a first axis which is at a predefined first angle with the one surface of the plate; a second portion connected to and further bent to extend from the first portion through a second bending joint, the second portion is arranged to extend along a second axis which is at a predefined second angle with the one surface of the one surface of the plate, where the first angle is steeper than the second angle; and a third portion comprising the snapping feature, and connected to and further bent to extend from the second portion through a third bending joint, the third portion is arranged to extend along a third axis which is at a predefined third angle relative to the one surface of the plate, where the third angle being different than the second angle. Further, the each snapping clip may be configured such that the corresponding each snapping feature can move upward from the plate when the corresponding one LED board is moved toward the predefined position between the plate and the corresponding each snapping clip, and, when the predefined position is reached, the snapping feature can move downward to the corresponding opening in the housing wall to snap. Still further, the upward and downward movement of the corresponding each feature may be facilitated by any combination of the first, second and third bending joints.

### BRIEF DESCRIPTION OF THE DRAWINGS

These and other features and aspects of the present disclosure will become better understood when the following detailed description is read, with reference to the accompanying drawings, in which like characters represent like parts throughout the drawings, wherein:

FIGS. 1A and 1B are exemplary views (a 3-dimensional view in FIG. 1A and a two-dimensional view in FIG. 1B) of a snapping clip on a housing plate/housing fixture for assembling LED boards, according to an embodiment of the invention;

FIGS. 2A and 2B depict an exemplary snapping process using a snapping clip on a housing plate when an LED board is moved toward a predefined position between the plate and the snapping clip, according to an embodiment of the invention;

FIGS. 3 and 4 are further illustrations of a process shown in FIGS. 2A and 2B, where FIG. 3 is an exemplary view of one LED board being in the process of inserted into a snapping clip 14 with a snapping feature (claw) being raised before snapping, and where FIG. 4 is an exemplary view of one LED board inserted into three snapping clips and snapped on a housing plate, according to corresponding embodiments of the invention; and

FIG. 5 is an exemplary view of a housing with a plate comprising eleven rows of snapping clips with three clips in each row, assembled with eleven LEDs, according to an embodiment of the invention.

### DETAILED DESCRIPTION

A new lighting/housing fixture comprising a plate/housing plate having multiple snapping clips is presented for holding/assembling LED boards/modules in luminaires/LED light fixtures. The assembly can be made without any fasteners (such as rivets, screws, embossed fasteners, etc.), adhesive or any additional materials. This may be achieved by forming a housing plate comprising a plurality of snapping clips, made from one plate using, e.g., a sheet metal. The snapping clips are able to hold the LED boards in place, using snapped claws, as tight as conventional methods (e.g., using fasteners, rivets, etc.). In addition, the described housing fixture can simplify the assembling procedure, and reduce cost, manpower and maintenance compared to the conventional methods.

According to an exemplary embodiment, a housing fixture or a housing, for assembling light emitting diode (LED) boards, can comprise a plate, configured to hold one or more LED boards (modules). Such a plate can comprise one or more rows of snapping clips (identical or non-identical, e.g., having different dimensions) protruding from one surface of the plate. The snapping clips can be made by cutting and bending predefined features on the plate, and each row may comprise a plurality of snapping clips (e.g., two, three, etc.) for snapping a corresponding LED board of the one or more LED boards. Each snapping clip may be configured, when one of the one or more LED boards in a corresponding row of the one or more rows is moved to a predefined position between the plate and the corresponding snapping clip, to snap against a corresponding opening in a housing wall of the one LED board using a snapping feature (claw) of the snapping clip, to lock the one LED board on the plate without any further, components, fasteners or adhesives. In addition, the snap-in method, providing tight contacts of LED boards with the plate using snapping clips described herein, may help the LED boards with heat dissipation.

According to further embodiments, the plate with snapping clips can be made of a sheet metal, steel, aluminum, plastic and the like. Each snapping claw can be formed on the housing plate in one step using, e.g., a turret punching machine. Typically, a minimum thickness of the plate can be about 0.7 mm to provide enough holding force. Moreover, a maximum height of the snapping clip over the surface of the plate can be about three and a half times of a thickness of the plate. Other dimensions of the snapping clip such as maximum length and maximum width may be determined by capabilities of the turret punching machine.

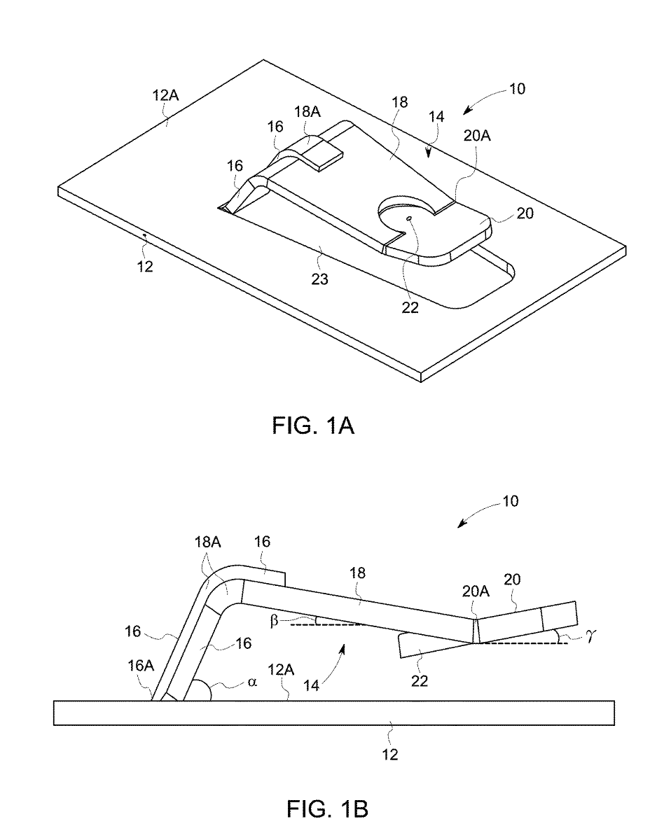

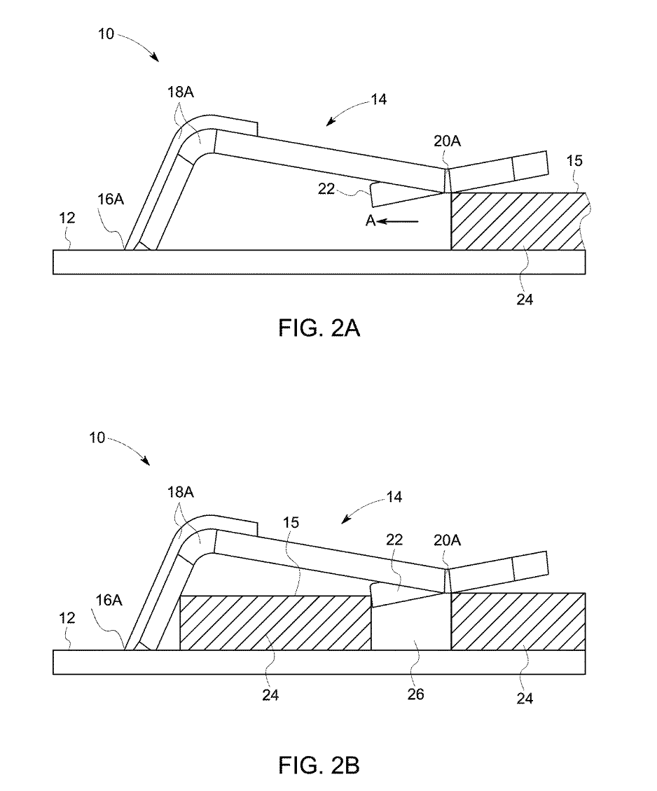

FIGS. 1A and 1B depict exemplary views (a 3-dimensional view in FIG. 1A and a two-dimensional view in FIG. 1B) of a snapping clip 14 on a plate 12 (only one area of the plate 12 is shown), which is a part of a housing 10, for assembling LED boards, according to an embodiment of the invention. The snapping clip 10 can comprise: a first portion 16 connected to and bent to extend from the top surface 12a of the plate 12 through a first bending joint 16a (as seen in FIG. 1B). The first portion 16 is arranged to extend along a first axis which is at a predefined first angle α with the plate (or the top surface 12a). A second portion 18 is connected to and further bent to extend from the first portion 16 through a second bending joint 18a. The second portion 18 is arranged to extend along a second axis which is at a predefined second angle β with the plate 12 (or the top surface 12a), where the first angle α is steeper than the second angle β. A third portion 20, comprising the snapping feature (claw) 22, is connected to and further bent to extend from the second portion 18 through a third bending joint 20a. The third portion 20 is arranged to extend along a third axis which is at a predefined third angle [symbol] relative to the plate 12. It is noted that a distal end of the clipping feature 22 is the closest to the top surface 12a of the plate 12 than any other area of the second and third portions 18 and 20 respectively, where the third angle [symbol] is different than the second angle β. Also, a distance from the distal end of the clipping feature 22 to the top surface 12a of the plate 12 is smaller than a height of the corresponding one LED board to be inserted into the snapping clip 14 (e.g., see FIG. 2A).

Furthermore, as stated herein, each snapping claw, like the claw 14 can be formed on the housing plate 12, e.g., in one step using a turret punching machine, by cutting an opening 23 in the plate 12 and forming the clip 14. The clipping feature (claw) 22 can have a circle shape, a rectangular shape, a triangular shape and the like to match a corresponding opening in the LED board, which is illustrated in FIG. 2B.

FIGS. 2A and 2B illustrate an exemplary snapping process of the snapping clip 14 when an LED board 24 (shown in a cross-section), is moved in a direction A toward a predefined position between the plate 12 and the snapping clip 14 according to an embodiment of the invention. In FIG. 2A, the LED board 24 is moved in the direction A toward the clip 14 and reaches an area around a third bending joint 20a. As seen in FIG. 2A, in order to continue movement in the direction A, the snapping feature 22 has to move upward. When the LED 24 board continues to move in the direction A toward the predefined position, the snapping clip 14 is configured such that the snapping feature (claw) 22, while being in a rolling contact with a housing wall 15 of the LED board 24, moves upward, which is facilitated by any combination of the first, second and third bending (flexible) joints 16a, 18a and 20a, respectively, due to their elastic properties.

FIG. 2B demonstrates a snapped position of the clip 14 when the predefined position of the LED board 24 is reached, so that the snapping feature (claw) 22 moves downward to a corresponding opening 26 in the housing wall of the LED 24 to snap. The downward movement of the snapping feature (claw) 22 is facilitated by any combination of the first, second and third bending joints 16a, 18a and 20a, respectively, due to their spring-like properties. The snapping force of the LED board 24, using multiple snapping clips like the clip 14, can be compatible with the holding forces achievable using conventional methods such as using fasteners/rivets.

It is further noted that the clamping demonstrated in FIG. 2B can be reversible. In other words, in some applications, the clamping can be released by using a prying tool (or a simple screwdriver) applied, for example, to the second and/or third sections of the clip 14 to lift/release the clipping feature (claw) 22 from the opening 26 in the LED board 24 and simultaneously move the LED board 24 in a direction opposite to the A direction.

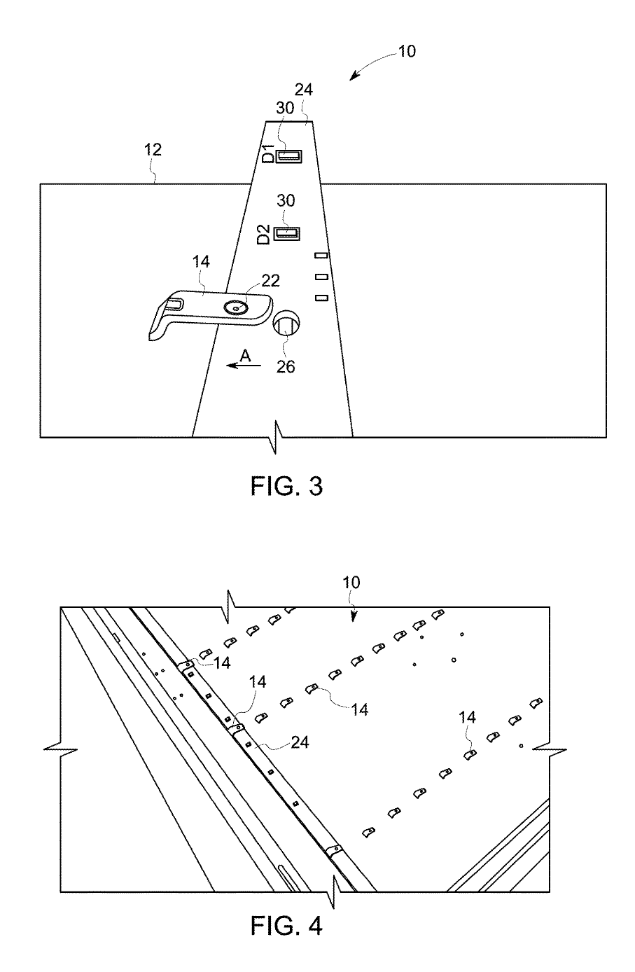

FIGS. 3 and 4 further illustrate the process shown in FIGS. 2A and 2B. FIG. 3 shows an exemplary view of one LED board 24 being in the process of inserted into the snapping clip 14 and corresponds to a situation when the LED board has already passed the area around a third bending joint 20a indicated in FIG. 2A. The snapping feature (claw) 22 is in the upward position as explained above, so that the LED board can be further inserted/moved in the direction A until reaching the predefined position where the clapping feature (claw) 22 reaches an edge of the opening 26 in the LED board 24. At this point, the snapping feature (claw) 22 moves downward to the corresponding opening 26 in the housing wall of the LED 24 to snap, as illustrated in a cross-sectional view in FIG. 2A. The LED board 24 comprises light sources 30 periodically located along its length. FIG. 4 shows one LED board 24 inserted into three snapping clips 14 and snapped as described herein.

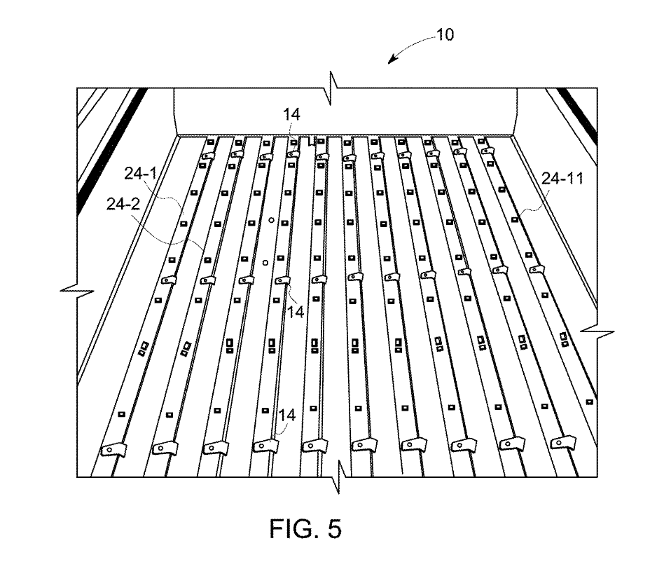

FIG. 5 is an exemplary view of a housing 10 comprising eleven rows of snapping clips 14, three clips in each row, assembled with eleven LED boards 24-1, 24-2, . . . , and 24-11 as described herein. Three clips 14 are used for holding each of the eleven LED boards.

Unless defined otherwise, technical and scientific terms used herein have the same meaning as is commonly understood by one having ordinary skill in the art to which this disclosure belongs. The terms “first”, “second”, and the like, as used herein, do not denote any order, quantity, or importance, but rather are employed to distinguish one element from another. Also, the terms “a” and “an” do not denote a limitation of quantity, but rather denote the presence of at least one of the referenced items. The use of “including,” “comprising” or “having” and variations thereof herein are meant to encompass the items listed thereafter and equivalents thereof, as well as additional items. The terms “connected” and “coupled” are not restricted to physical or mechanical connections or couplings, and can include electrical and optical connections or couplings, whether direct or indirect.

Furthermore, the skilled artisan will recognize the interchangeability of various features from different embodiments. The various features described, as well as other known equivalents for each feature, can be mixed and matched by one of ordinary skill in this art, to construct additional systems and techniques in accordance with principles of this disclosure.

In describing alternate embodiments of the apparatus claimed, specific terminology is employed for the sake of clarity. The invention, however, is not intended to be limited to the specific terminology so selected. Thus, it is to be understood that each specific element includes all technical equivalents that operate in a similar manner to accomplish similar functions.

It is to be understood that the foregoing description is intended to illustrate and not to limit the scope of the invention, which is defined by the scope of the appended claims. Other embodiments are within the scope of the following claims.

It is noted that various non-limiting embodiments described and claimed herein may be used separately, combined or selectively combined for specific applications.

Further, some of the various features of the above non-limiting embodiments may be used to advantage, without the corresponding use of other described features. The foregoing description should therefore be considered as merely illustrative of the principles, teachings and exemplary embodiments of this invention, and not in limitation thereof.

1. A housing fixture for assembling light emitting diode (LED) boards, the housing fixture comprising:
a plate, configured to hold one or more LED boards, the plate comprising:
one or more rows of snapping clips protruding from one surface of the plate and made by cutting and bending predefined features on the plate, each row comprises a plurality of snapping clips for snapping a corresponding LED board of the one or more LED boards,
wherein each snapping clip of the plurality of snapping clips is configured, when one o the one or more LED boards in a corresponding row of the one or more rows is moved to a predefined position between the plate and said each snapping clip, to snap against a corresponding opening in a housing wall of the one LED board using a snapping feature of said each snapping clip, to lock the one LED board with the plate without any further components, fasteners or adhesives.

2. The housing fixture of claim 1, wherein the corresponding snapping feature moves upward from the plate when the corresponding one LED board is moved toward the predefined position between the plate and the corresponding snapping clip, and, when the predefined position is reached, the snapping feature moves downward to the corresponding opening in the housing wall of the one LED board to snap.

3. The housing fixture of claim 1, wherein the snapping feature is a claw.

4. The housing fixture of claim 1, wherein the plate is made of a sheet metal.

5. The housing fixture of claim 4, the sheet of metal comprises a steel.

6. The housing fixture of claim 1, wherein the plate is made of aluminum.

7. The housing fixture of claim 1, wherein all snapping clips are identical.

8. The housing fixture of claim 1, wherein at least one row of snapping clips has different dimensions than at least one further row of snapping clips to accommodate LED boards having different dimensions.

9. The housing fixture of claim 1, wherein a thickness of the plate is 0.7 mm or more.

10. The housing fixture of claim 1, wherein a maximum height of the each snapping clip over the one surface of the plate is approximately three and a half times of a thickness of the plate.

11. The housing fixture of claim 1, wherein the snapping feature has a round shape.

12. The housing fixture of claim 1, wherein the snapping feature has a rectangular shape.

13. The housing fixture of claim 1, wherein a row of the one or more rows comprises two snapping clips.

14. The housing fixture of claim 1, wherein a row of the one or more rows comprises three snapping clips.

15. The housing fixture of claim 1, where the each snapping clip comprises:
a first portion connected to and bent to extend from the one surface of the plate through a first bending joint, the first portion is arranged to extend along a first axis which is at a predefined first angle with the one surface of the plate;
a second portion connected to and further bent to extend from the first portion through a second bending joint, the second portion is arranged to extend along a second axis which is at a predefined second angle with the one surface of the one surface of the plate, where the first angle is steeper than the second angle; and
a third portion comprising the snapping feature, and connected to and further bent to extend from the second portion through a third bending joint, the third portion is arranged to extend along a third axis which is at a predefined third angle relative to the one surface of the plate, where the third angle being different than the second angle.

16. The housing fixture of claim 15, wherein the each snapping clip is configured such that the corresponding each snapping feature moves upward from the plate when the corresponding one LED board is moved toward the predefined position between the plate and the corresponding each snapping clip, and, when the predefined position is reached, the snapping feature moves downward to the corresponding opening in the housing wall to snap.

17. The housing fixture of claim 16, wherein the upward and downward movement of the corresponding each feature is facilitated by any combination of the first, second and third bending joints.

18. The housing fixture of claim 15, wherein a distal end of the clipping feature is the closest to the one surface of the plate than any other point of the second and third portions.

19. The housing fixture of claim 1, wherein a distance from a distal end of the clipping feature to the one surface of the plate is smaller than a height of the corresponding one LED board.

20. The housing fixture of claim 1, wherein any of the one or more LED boards is removable.
